(19) United States
(12) Patent Application Publication
(10) Pub. No.: US 2024/0176932 A1
(43) Pub. Date: May 30, 2024

(54) CONTINUOUS ONLINE VALIDATION OF PROCESS MEASUREMENTS IN DIGITAL TWINS

(71) Applicant: Saudi Arabian Oil Company, Dhahran (SA)

(72) Inventors: Hassan Mohammadali Al Matouq, Al Qatif (SA); Mohamed Ahmed Soliman, Oakville (CA); Rida Majed Bin Hashim, Safwa (SA)

(21) Appl. No.: 18/071,243

(22) Filed: Nov. 29, 2022

(51) Int. Cl. G06F 30/27

(52) U.S. Cl. CPC G06F 30/27

(57) ABSTRACT

Systems and methods include a method for monitoring sensors. Readings of actual field sensors corresponding to virtual sensors of a virtual model are monitored. A deviation between an actual sensor reading (ASR) and a virtual sensor reading (VSR) is determined. When only the VSR is deviating and when sensor readings of sensors proximate to the actual sensor correspond to the VSR, then the ASR is invalid and the actual sensor requires revalidation/recalibration. When only the ASR is deviating and when sensor readings of sensors proximate to the actual sensor correspond to the ASR, then the VSR is invalid and the virtual sensor requires revalidation/recalibration. When both the VSR and ASR are deviating from design ranges and when sensor readings of sensors that are proximate to the actual sensor do not correspond to either the ASR or the VSR, then both the ASR and VSR are invalid, requiring revalidation/recalibration.

### TECHNICAL FIELD

The present disclosure applies to the use of sensors, such as in oil or gas facilities.

### BACKGROUND

Reliable sensor measurements are essential for optimal process control. If a crucial process sensor fails to deliver an accurate reading, the system control can lead to faults or even an unwanted system shutdown. Using multiple physical sensors for the same parameter is usually associated with cost due to multiple installations and maintenance. Digital twins of process facilities provide a replica (virtual model) of the physical devices. However, even when a virtual sensor is used, there is no tool that can determine whether the physical or virtual sensor is valid.

### SUMMARY

The present disclosure describes techniques that can be used for using different types of actual and virtual sensors to determine that one or both of the actual and virtual sensors require revalidation and recalibration. In some implementations, a computer-implemented method includes the following. Readings of actual field sensors corresponding to virtual sensors modeled in a virtual model are monitored. A deviation between an actual sensor reading (ASR) and a virtual sensor reading (VSR) is determined. When only the VSR is deviating and when sensor readings of sensors that are proximate to the actual sensor correspond to the VSR, then a determination is made that the ASR is invalid and that the actual sensor requires revalidation and recalibration. When only the ASR is deviating and when sensor readings of sensors that are proximate to the actual sensor correspond to the ASR, then a determination is made that the VSR is invalid and that the virtual sensor requires revalidation and recalibration. When both of the VSR and the ASR are deviating from their respective design ranges and when sensor readings of sensors that are proximate to the actual sensor do not correspond to either the ASR or the VSR, then a determination is made that both the ASR and the VSR are invalid and that both the actual sensor and the virtual sensor require revalidation and recalibration.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, the instructions stored on the non-transitory, computer-readable medium.

The subject matter described in this specification can be implemented in particular implementations, so as to realize one or more of the following advantages. Techniques of the present disclosure can be used to solve the technical problem of incorrect physical sensor readings. These problems can be compounded by the lack of automatic sensor validation tools. The techniques of the present disclosure can provide methods and systems for performing online automatic validation of process variables. Validating online process measurements can provide an advantage over conventional systems by providing algorithms to identify whether an actual or virtual sensor reading is valid (or invalid). Such algorithms can use at least two main sources to validate process measurements, including using online virtual sensor readings and an offline simulation/machine learning model based on a process physical model. Conventional approaches are typically unable to identify whether an actual or a virtual sensor reading is valid (or invalid). Moreover, conventional approaches typically do not provide a system that can be integrated with a digital twin to perform continuous validation. Algorithms described in the present disclosure are general enough to be used to validate any process measurement. The techniques can be integrated with digital twin and plant control systems.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 is a flow diagram of a workflow for validating sensors, according to some implementations of the present disclosure.

FIG. 2 is a diagram showing an example of a temperature sensor configuration, according to some implementations of the present disclosure.

FIG. 3 is a diagram showing an example of a pressure sensor configuration, according to some implementations of the present disclosure.

FIG. 4A is a diagram showing an example of a flow sensor configuration, according to some implementations of the present disclosure.

FIG. 4B is a diagram showing an example of a level and flow sensor configuration, according to some implementations of the present disclosure.

FIG. 5 is a block diagram showing an example of a hardware architecture, according to some implementations of the present disclosure.

FIG. 6 is a block diagram showing an example of an architecture for process variable validation, according to some implementations of the present disclosure.

FIG. 7 is a flowchart of an example of a method for using different types of actual and virtual sensors to determine that one or both of the actual and virtual sensors require revalidation and recalibration, according to some implementations of the present disclosure.

FIG. 8 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The following detailed description describes techniques that can be used for using different types of actual and virtual sensors to determine that one or both of the actual and virtual sensors require revalidation and recalibration. Various modifications, alterations, and permutations of the disclosed implementations can be made and will be readily apparent to those of ordinary skill in the art, and the general principles defined may be applied to other implementations and applications, without departing from the scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

Techniques of the present disclosure provide a method and system for the continuous online automated validation of a process measurement (e.g., a physical sensor reading). The validation is based on a virtual sensor reading and the physical (design) correlation with other related process parameters such as pressure, temperature, flow, and level. An algorithm described in the present disclosure takes as inputs the actual reading of the process variable to be monitored and the corresponding virtual sensor reading. As an example, to determine which sensor is correct and which sensor requires revalidation or calibration, the algorithm first calculates the deviation of each sensor from the other. For the deviating sensor, the algorithm checks whether the sensor reading matches the actual readings of the surrounding (related) sensors in the plant-based on physical (design) correlation. The sensor that does not match its related sensors is considered to be not correct and therefore requires revalidation/recalibration.

Techniques of the present disclosure can be used to complement the process of digital twins by providing online validation of real-time sensor readings. The term real-time can correspond, for example, to events that occur within a specified period of time, such as within one minute. For example, the sensor readings can be received in real time, such as at one-second intervals. The validation can then be performed in real-time as well, such as within a few seconds after receipt of the sensor readings. The validation results can be reflected on process flow diagrams displayed on the human-machine interface (HMI) of process automation systems including Distributed Control Systems (DCS), Supervisory Control & Data Acquisition (SCADA), and Data Historian & Archiving Systems (DAHS). The validation results can also be used by a controller in a process control system to select between the actual and the virtual sensor readings when making the decision on the required control action or adjustment of a field actuator.

Features provided by the techniques of the present disclosure can include: 1) a method for online automatic validation of process measurements using processing circuitry, 2) an apparatus for automatic validation of process measurements, and 3) a non-transitory computer-readable medium to store computer instructions to perform the method;

### Algorithm for Automated Validation of a Process Measurement

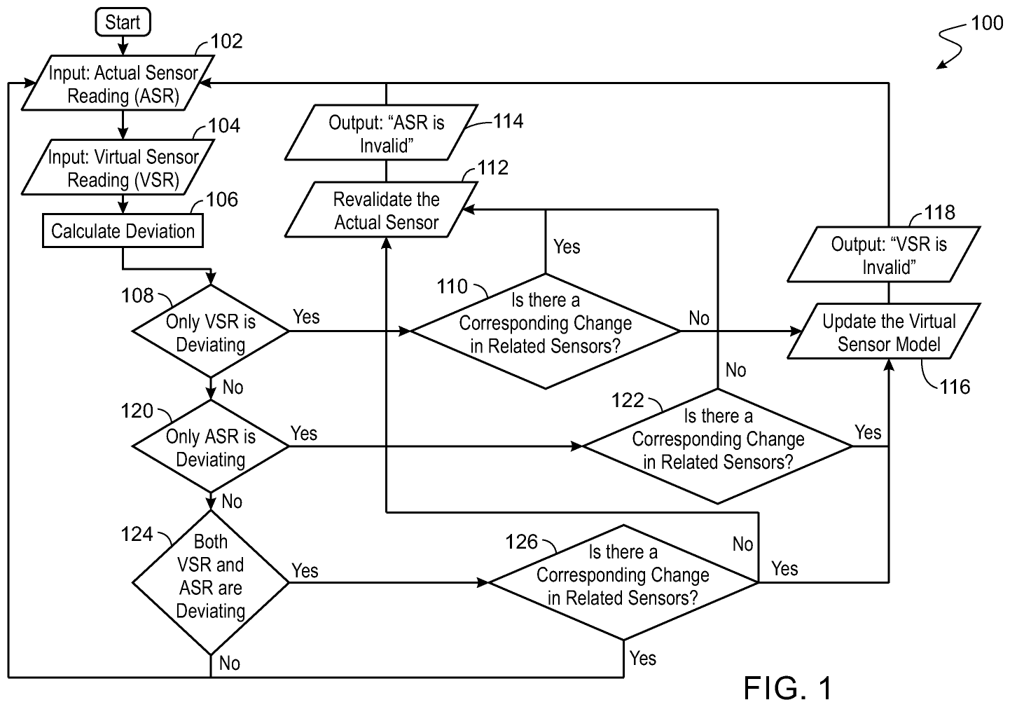

FIG. 1 is a flow diagram of a workflow 100 for validating sensors, according to some implementations of the present disclosure. The workflow 100 can represent an algorithm for the automated validation of process measurements, including the following steps.

An actual sensor reading (ASR) 102 is obtained corresponding to an actual field sensor to be monitored, and a virtual sensor reading (VSR) 104 of the corresponding virtual sensor is obtained. The virtual sensor can be constructed using any inferential method such as an online simulator or a digital twin that is fed with real-time actual process sensor readings.

A deviation D between the actual and virtual sensor readings is determined. In one example, the deviation D can be calculated (106) based on instantaneous readings using the formula in Equation (1):

$$D = \frac{V S R - A S R}{V S R} * 100 \qquad ( 1 )$$

where VSR is a virtual sensor reading 104, and ASR is the actual sensor reading 102.

In another example, the deviation D can be determined based on historical readings from both sensors over a time T (e.g., minutes or days). In this example, the historical readings can be used to calculate the average deviation or the correlation coefficient between them.

If only VSR is deviating (e.g., if the deviation D of Equation (1) is greater than a pre-determined positive threshold and there is minor change (or no change) in ASR previous values over specified period of time), and if there is a corresponding change in the related sensors (determined at 110), then it is concluded that the ASR is invalid and requires revalidation/recalibration (112). A notification 114 can be output that indicates that the ASR is invalid. If the VSR is deviating, and if there is no corresponding change in the related sensors, then it is concluded that the virtual sensor model is invalid and needs to be updated (116). A notification 118 can be output that indicates that the VSR is invalid.

At 120, if only ASR is deviating (e.g., if the deviation D of Equation (1) is less than a pre-determined negative threshold and there is minor change (or no change) in VSR previous values over specified period of time), and if there is a corresponding change in the related sensors (determined at 122), then it is concluded that the virtual sensor model is invalid and needs to be updated (116). If the ASR is deviating, and if there is no corresponding change in the related sensors, then it is concluded that the ASR is invalid and requires revalidation/recalibration (112).

If both the VSR and the ASR are deviating (determined at 124) from pre-determined threshold values (e.g., design ranges), and if there is no corresponding change in the related sensors (determined at 126), then it is concluded that both the VSR and the ASR need to be revalidated.

For a sensor currently under validation, the changes that occur in related (e.g., surrounding or adjacent) sensors of the sensor being validated can be identified in different ways. In a first example method of identifying changes in the related (e.g., surrounding or adjacent) sensor, a set of validation rules (e.g., one or more of mathematical functions or inequalities between the sensors) can be constructed based on the physical model of the process. A second example method of identifying changes in the related (e.g., surrounding or adjacent) sensor is to construct an offline simulation model based on the process design conditions, from which a table correlating the sensors can be extracted. A third example method of identifying changes in the related (e.g., surrounding or adjacent) sensor can include constructing a machine learning model correlating the sensor with its related sensors.

### Model Using Sensors in Proximity

A model can exist which takes advantage of process sensors that are within proximity and in which there are no changes in certain properties of the sensors. In this case, the sensors can be used to validate each other using readings from one or more of temperature, flow, pressure, and level sensors that are nearby.

### Temperature Sensors

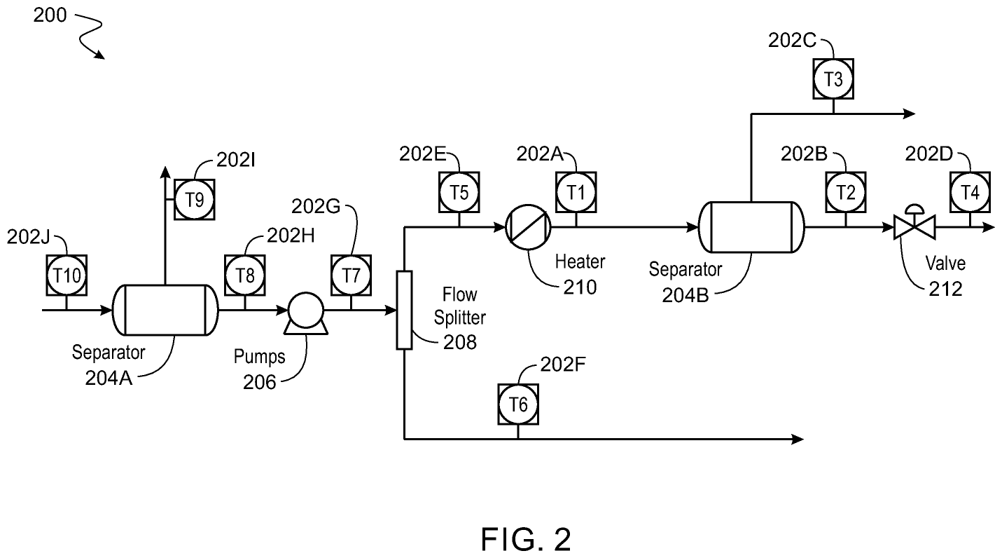

FIG. 2 is a diagram showing an example of a temperature sensor configuration 200, according to some implementations of the present disclosure. In the temperature sensor configuration 200, heating or cooling are the only processes that can change the temperature significantly for liquid operations. Temperature sensors 202A-202D (T1, T2, T3, and T4) can be used in validation against each other while temperature sensors 202E-202J (T5, T6, T7, T8, T9, and T10) can be used in validation against each other. Variations in the T1-T4 group or the T5-T10 group can typically be within 10%, for example, depending on the value of the operating temperature. Temperature sensors 202A-202D (T1-T4) normally record higher temperatures than temperature sensors 202E-202J (T5, T6, T7, T8, T9, T10), e.g., due to the direction of flow and use of heater 210. The temperature sensor configuration 200 also shows separators 204A and 204B, pumps 206, a flow splitter 208, and a valve 212.

### Pressure Sensors

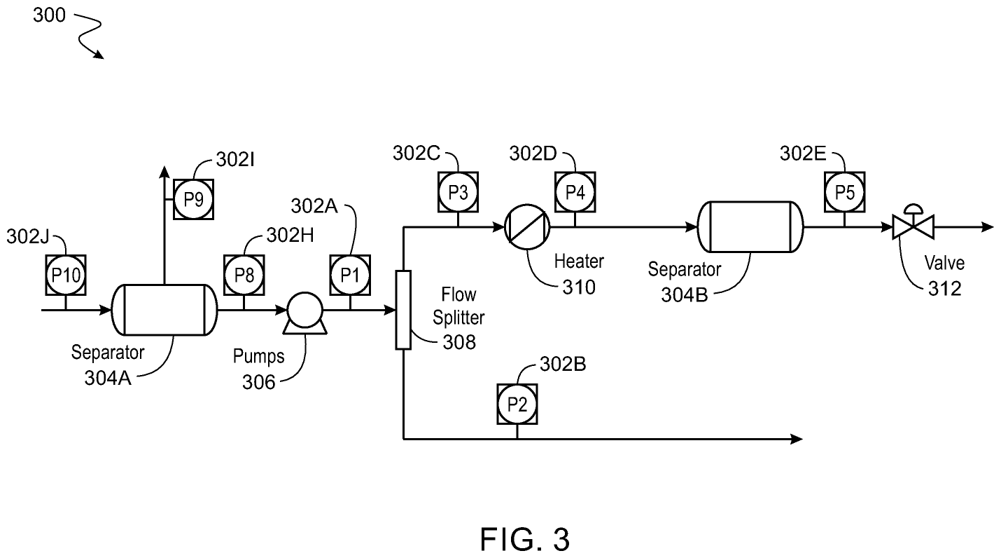

FIG. 3 is a diagram showing an example of a pressure sensor configuration 300, according to some implementations of the present disclosure. In the pressure sensor configuration 300, pumps are the only processes that can change the pressure significantly for liquid operations. Pressure sensors 302A-302E (P1, P2, P3 and P4, and P5) can be used in validation against each other while pressure sensors 302H-302J (P8, P9, and P10) can be used in validation against each other. Variation in P1-P5 groups or P8-P10 groups can be within 10%, depending on the value of the operating pressure. The pressure sensor configuration 300 also shows separators 304A and 304B, pumps 306, a flow splitter 308, and a heater 310.

The pressures obtained from pressure sensors P1-P5 are normally higher than the pressures obtained from pressure sensors P8-P10. For example, if the pressure of pressure sensor P1 is deviating while there are no significant changes in the pressures of pressure sensors P2, P3, P4, and P5, then there is a problem with pressure sensor P1, indicating that pressure sensor P1 requires attention. Significant changes are normally defined as changes that are greater than 5%, for example. The same applies to pressures P8-P10.

### Flow Sensors

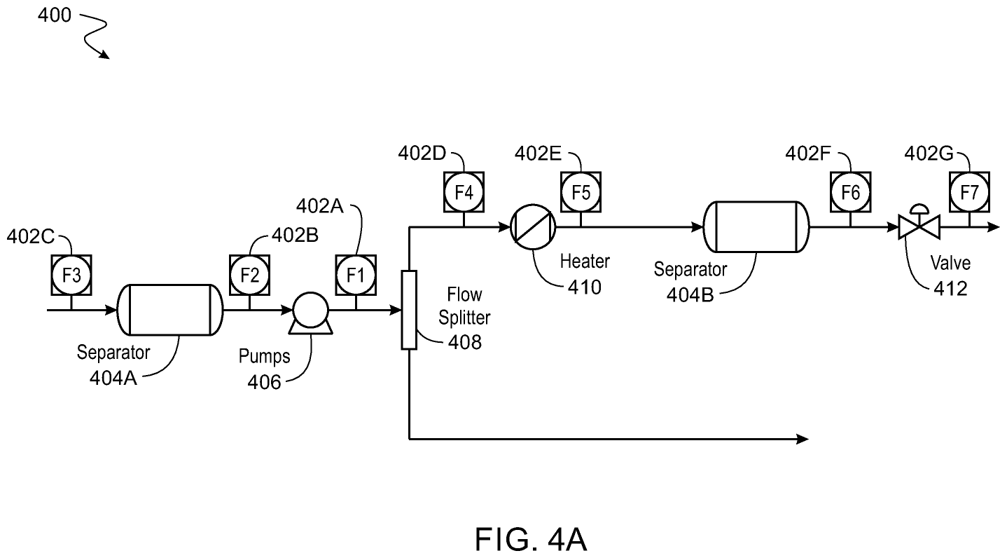

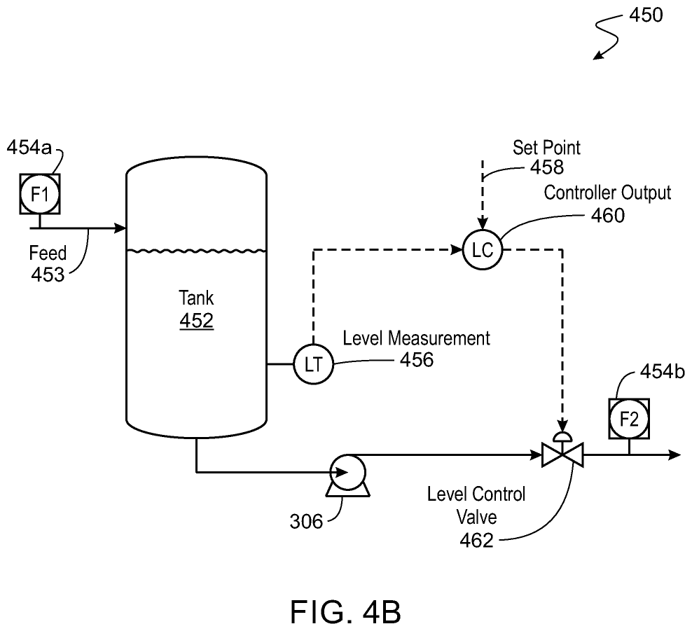

FIG. 4A is a diagram showing an example of a flow sensor configuration 400, according to some implementations of the present disclosure. In the flow sensor configuration 400, flow splitter 408 is one of the processes that can change the flow significantly for liquid operations as shown below. Flow sensors 402A-402C (F1, F2, and F3) can be used in validation against each other while flow sensors 402D-402G (F4, F5, F6, and F7) can be used in validation against each other. Variation in the flow sensors F1-F3 group or the flow sensors F4-F7 group can typically be within 10%, for example, depending on the value of the operating flow. The flow sensor configuration 400 also shows separators 404A and 404B, pumps 406, a flow splitter 408, a heater 410, and a valve 412.

Flow rates of flow sensors F1-F3 are normally higher than the flow rates of flow sensors F4-F7. For example, if the flow rates of flow sensor F4 are deviating while there are no significant changes in the flow rates of flow sensors F5, F6, and F7, then there is a problem with flow sensor F4 that requires attention. “Significant” changes are normally defined as changes that are higher than 5%, for example. The same applies to flow sensors F1-F3.

### Level Sensors

FIG. 4B is a diagram showing an example of a level and flow sensor configuration 450, according to some implementations of the present disclosure. In the level and flow sensor configuration 450, the sensors are related and can be used to validate the level readings. However, it is noted that the flow sensors are validated according to the Flow Sensors section above.

A change in a tank's level (e.g., tank 452) is a result of flow from (and a feed 453 into) the tank. Therefore, a level sensor can be validated by using the data from feed and outlet flow meters, e.g. flow meter 454a (“F1”) and flow meter 454b (“F2”). The validation can be performed using a mass balance equation, e.g., conducted over some time period (t):

$$Δ {L}_{b} = \frac{F 1 - F 2}{C} \qquad ( 2 )$$

where ΔL_{b} is change in level obtained by the balance equation, and C is a cross-sectional area of the tank. This equation assumes that the density of the fluid is constant and equal at F1, F2, and within the tank. This will be the case in most practical circumstances. However, the balance equation can be modified to add a density correction in case a correction is needed. Moreover, a variable cross-sectional C(L) can be used with some modification to the equation.

To illustrate resolving a deviation between the level ASR and VSR, their ΔL over some time period can be compared to ΔL_{b} obtained from the mass balance equation (Equation (2)). The sensor with the largest absolute difference |ΔL_{b}−ΔL| is reported to be invalid, provided that the absolute difference is significant. “Significant” is normally defined as a deviation of a magnitude greater than 10% of ΔL, for example. Systems including a tank typically include a set point 758, a controller output 760, and a level control valve 762, which can affect the level and the flow.

### Proposed Apparatus

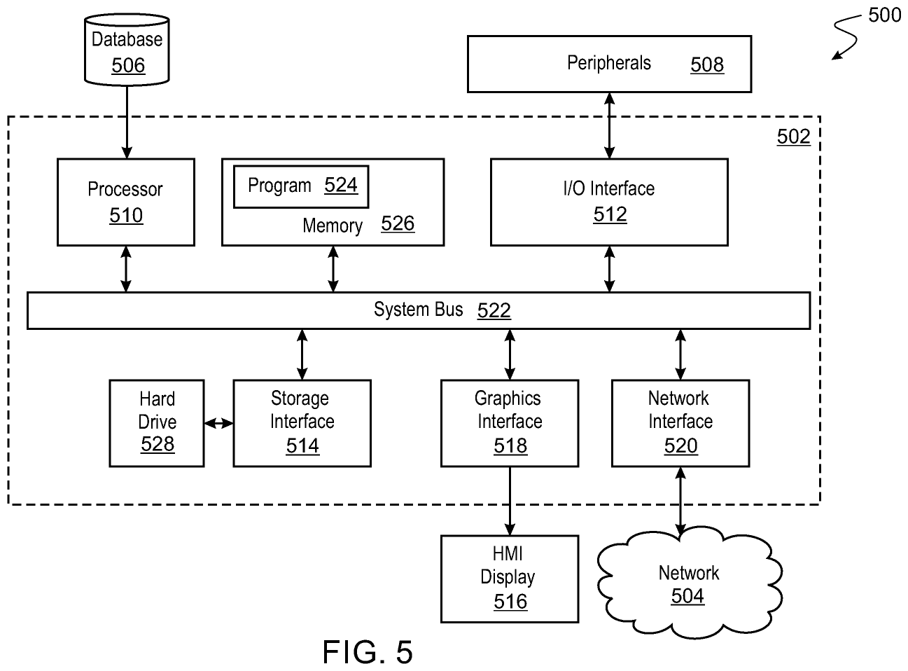

FIG. 5 is a block diagram showing an example of a hardware architecture 500, according to some implementations of the present disclosure. For example, the hardware architecture 500 can represent an apparatus 502 and its hardware that can be used to perform the techniques described in the present disclosure. The circuitry of the apparatus is interfaced with the network 504, database 506, peripherals 508, and a human-machine interface (HMI) display 516. The database 506 can store information about the set of sensors and their corresponding virtual sensors and related (surrounding) sensors. The database 506 can also store any information required to identify a change in the related sensors such as mathematical rules (inequalities), simulation models, or machine learning models. The network 504 can be used by the apparatus 502 to communicate with one or more DCS/SCADA/DAHS systems to acquire real-time process variables to be validated.

The apparatus 502 includes a processer 510 (e.g., central processing unit (CPU)) which performs the proposed method and algorithms for validating the process variables. The apparatus 502 also includes controllers for I/O (e.g., I/O interface 512), a storage interface 514, a human-machine interface (HMI) for the HMI display 516, graphics interfaces 518, and network interfaces 520. These components communicate with each other through the system bus 522.

The instructions and process data that are used to carry out the method may be stored as a program 524 in the memory 526, hard drive (HDD) 528, remotely, or on any tangible computer-readable storage media. When these instructions are executed by the processor 510, the instructions can cause the processor 510 to perform the process variables validation using the techniques described in the present disclosure.

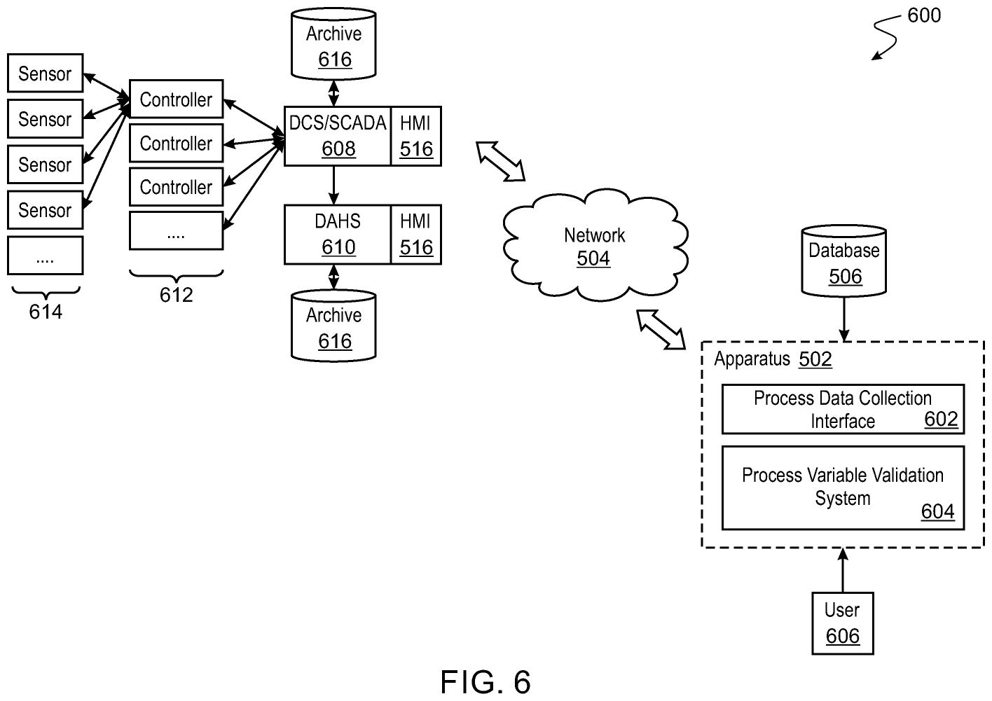

FIG. 6 is a block diagram showing an example of an architecture 600 for process variable validation, according to some implementations of the present disclosure. The architecture 600 can be used for the apparatus 502, for example. In this example, the apparatus 502 includes a process data collection interface 602 and a process variable validation system 604 that can be used by a user 606. HMI interfaces 516 for DCS and SCADA systems 608 and a DAHS 610 can provide access by users through the network 504. The DCS and SCADA systems 608 can execute and interface with controllers 612 corresponding to sensors 614. Data can be archived in archives 616.

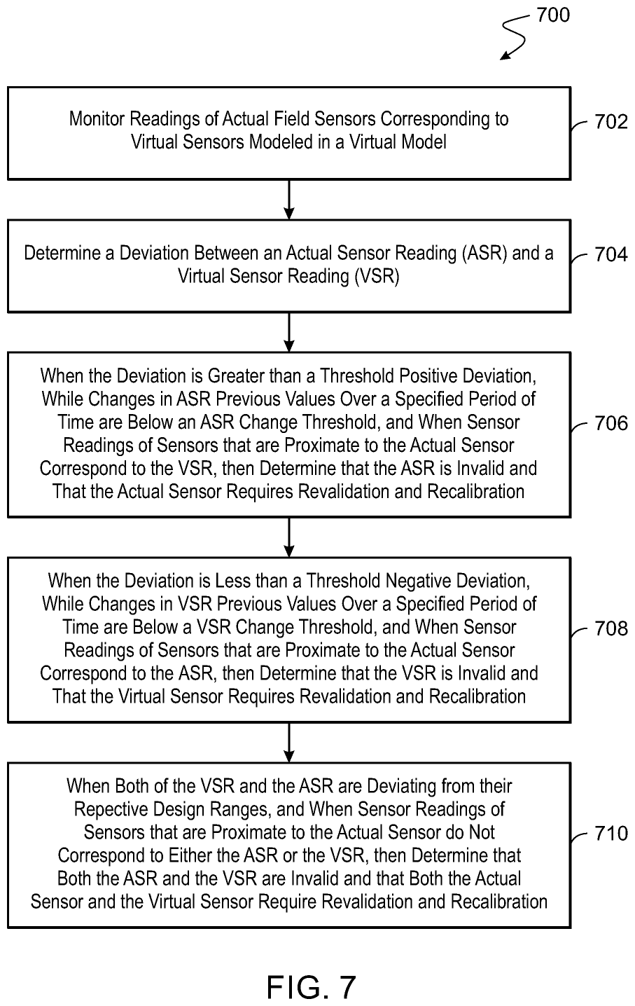

FIG. 7 is a flowchart of an example of a method 700 for using different types of actual and virtual sensors to determine that one or both of the actual and virtual sensors require revalidation and recalibration, according to some implementations of the present disclosure. For clarity of presentation, the description that follows generally describes method 700 in the context of the other figures in this description. However, it will be understood that method 700 can be performed, for example, by any suitable system, environment, software, and hardware, or a combination of systems, environments, software, and hardware, as appropriate. In some implementations, various steps of method 700 can be run in parallel, in combination, in loops, or in any order.

At 702, readings are monitored of actual field sensors corresponding to virtual sensors modeled in a virtual model. For example, the actual field sensors can include temperature sensors, pressure sensors, and flow sensors. From 702, method 700 proceeds to 704.

At 704, a deviation is determined between an actual sensor reading (ASR) and a virtual sensor reading (VSR). The deviation can be determined using Equation (1), for example. In some implementations, determining the deviation between the ASR and the VSR can include performing calculations using instantaneous sensor readings. In some implementations, determining the deviation between the ASR and the VSR can be based on average deviations of historical readings from both types of sensors over a designated time period. In some implementations, determining that the sensor readings of the sensors that are proximate to the actual sensor correspond to the sensor can include using a set of validation rules. For example, the set of validation rules can include mathematical functions based on inequalities between the sensors. The validation rules can also include features that analyze trends in readings over time, such as trends in one sensor that do not match (e.g., within a percentage or absolute threshold) trends of one or more proximate sensors of the same or different types. From 704, method 700 proceeds to 706.

At 706, when the deviation (e.g., based on Equation (1)) is greater than a threshold positive deviation, while changes in ASR previous values over a specified period of time are below an ASR change threshold (e.g., with a minor change (or no change) in ASR previous values over the specified period of time), and when sensor readings of sensors that are proximate to the actual sensor correspond to the VSR, then a determination is made that the ASR is invalid and that the actual sensor requires revalidation and recalibration. From 706, method 700 proceeds to 708.

At 708, when the deviation (e.g., based on Equation (1)) is less than a threshold negative deviation, while changes in VSR previous values over a specified period of time are below a VSR change threshold (e.g., with a minor change (or no change) in VSR previous values over the specified period of time), and when sensor readings of sensors that are proximate to the actual sensor correspond to the ASR, then a determination is made that the virtual sensor is invalid and that the virtual sensor requires revalidation and recalibration. In some implementations, determining that the sensor readings of the sensors that are proximate to the actual sensor correspond to the sensor includes using a table correlating the sensors, wherein the table is generated from an offline simulation model based on process design conditions of multiple sensors. In some implementations, determining that the sensor readings of the sensors that are proximate to the actual sensor correspond to the sensor includes using a machine learning model correlating each sensor with its related sensors. From 708, method 700 proceeds to 710.

At 710, when both the VSR and the ASR are deviating from pre-determined threshold values (e.g., design ranges) and when sensor readings of sensors that are proximate to the actual sensor do not correspond to either the ASR or the VSR, then a determination is made that both the ASR and the VSR are invalid and that both the actual sensor and the virtual sensor require revalidation and recalibration. After 710, method 700 can stop.

In some implementations, in addition to (or in combination with) any previously-described features, techniques of the present disclosure can include the following. Outputs of the techniques of the present disclosure can be performed before, during, or in combination with hydrocarbon processing operations, such as to provide inputs to change the settings or parameters of a process control element. Examples of hydrocarbon processing operations include separation, degassing, desalting, dehydration, and gas compression, to name a few. The hydrocarbon processing operations can be triggered or controlled, for example, by outputs of the methods of the present disclosure. In some implementations, customized user interfaces can present intermediate or final results of the above described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or “app”), or at a central processing facility. The presented information can include suggestions, such as suggested changes in parameters or processing inputs, that the user can select to implement improvements in a production environment, such as in the production, and/or testing of petrochemical processes or facilities. For example, the suggestions can include parameters that, when selected by the user, can cause a change to, or an improvement in, hydrocarbon process parameters. The suggestions, when implemented by the user, can improve the speed and accuracy of calculations, streamline processes, improve models, and solve problems related to efficiency, performance, safety, reliability, costs, downtime, and the need for human interaction. In some implementations, the suggestions can be implemented in real-time, such as to provide an immediate or near-immediate change in operations or in a model. The term real-time can correspond, for example, to events that occur within a specified period of time, such as within one minute or within one second. Events can include readings or measurements captured by equipment such as sensors, pumps, compressors, or other equipment. The readings or measurements can be analyzed, such as by using applications that can include modeling applications and machine learning. The analysis can be used to generate changes to the settings of equipment, such as crude pumping equipment. In some implementations, values of parameters or other variables that are determined can be used automatically (such as through using rules) to implement changes in oil or gas operations. For example, outputs of the present disclosure can be used as inputs to other equipment and/or systems at a facility. This can be especially useful for systems or various pieces of equipment that are located several meters or several miles apart, or are located in different countries or other jurisdictions.

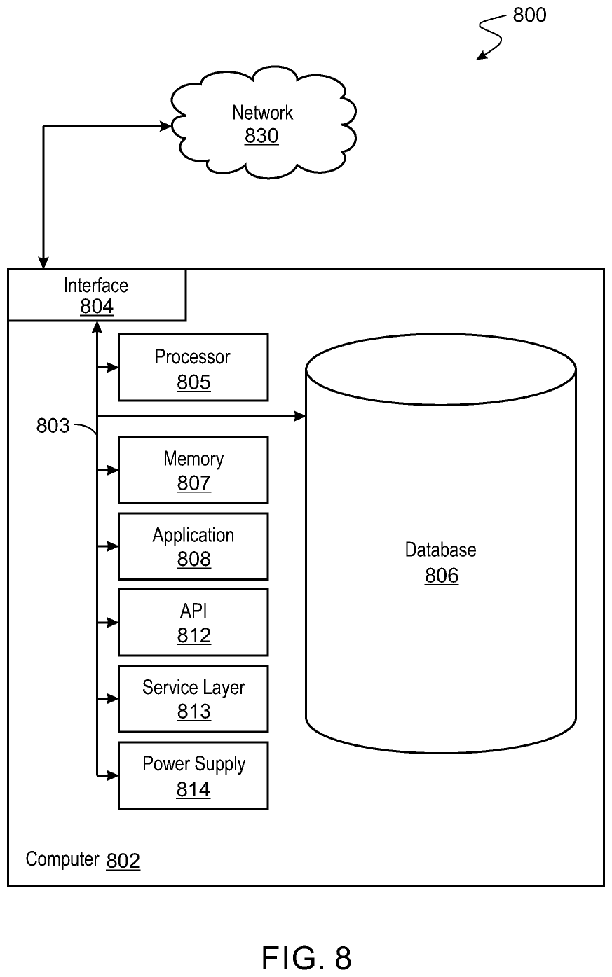

FIG. 8 is a block diagram of an example computer system 800 used to provide computational functionalities associated with described algorithms, methods, functions, processes, flows, and procedures described in the present disclosure, according to some implementations of the present disclosure. The illustrated computer 802 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 802 can include input devices such as keypads, keyboards, and touch screens that can accept user information. Also, the computer 802 can include output devices that can convey information associated with the operation of the computer 802. The information can include digital data, visual data, audio information, or a combination of information. The information can be presented in a graphical user interface (UI) (or GUI).

The computer 802 can serve in a role as a client, a network component, a server, a database, a persistency, or components of a computer system for performing the subject matter described in the present disclosure. The illustrated computer 802 is communicably coupled with a network 830. In some implementations, one or more components of the computer 802 can be configured to operate within different environments, including cloud-computing-based environments, local environments, global environments, and combinations of environments.

At a top level, the computer 802 is an electronic computing device operable to receive, transmit, process, store, and manage data and information associated with the described subject matter. According to some implementations, the computer 802 can also include, or be communicably coupled with, an application server, an email server, a web server, a caching server, a streaming data server, or a combination of servers.

The computer 802 can receive requests over network 830 from a client application (for example, executing on another computer 802). The computer 802 can respond to the received requests by processing the received requests using software applications. Requests can also be sent to the computer 802 from internal users (for example, from a command console), external (or third) parties, automated applications, entities, individuals, systems, and computers.

Each of the components of the computer 802 can communicate using a system bus 803. In some implementations, any or all of the components of the computer 802, including hardware or software components, can interface with each other or the interface 804 (or a combination of both) over the system bus 803. Interfaces can use an application programming interface (API) 812, a service layer 813, or a combination of the API 812 and service layer 813. The API 812 can include specifications for routines, data structures, and object classes. The API 812 can be either computer-language independent or dependent. The API 812 can refer to a complete interface, a single function, or a set of APIs.

The service layer 813 can provide software services to the computer 802 and other components (whether illustrated or not) that are communicably coupled to the computer 802. The functionality of the computer 802 can be accessible for all service consumers using this service layer. Software services, such as those provided by the service layer 813, can provide reusable, defined functionalities through a defined interface. For example, the interface can be software written in JAVA, C++, or a language providing data in extensible markup language (XML) format. While illustrated as an integrated component of the computer 802, in alternative implementations, the API 812 or the service layer 813 can be stand-alone components in relation to other components of the computer 802 and other components communicably coupled to the computer 802. Moreover, any or all parts of the API 812 or the service layer 813 can be implemented as child or sub-modules of another software module, enterprise application, or hardware module without departing from the scope of the present disclosure.

The computer 802 includes an interface 804. Although illustrated as a single interface 804 in FIG. 8, two or more interfaces 804 can be used according to particular needs, desires, or particular implementations of the computer 802 and the described functionality. The interface 804 can be used by the computer 802 for communicating with other systems that are connected to the network 830 (whether illustrated or not) in a distributed environment. Generally, the interface 804 can include, or be implemented using, logic encoded in software or hardware (or a combination of software and hardware) operable to communicate with the network 830. More specifically, the interface 804 can include software supporting one or more communication protocols associated with communications. As such, the network 830 or the interface's hardware can be operable to communicate physical signals within and outside of the illustrated computer 802.

The computer 802 includes a processor 805. Although illustrated as a single processor 805 in FIG. 8, two or more processors 805 can be used according to particular needs, desires, or particular implementations of the computer 802 and the described functionality. Generally, the processor 805 can execute instructions and can manipulate data to perform the operations of the computer 802, including operations using algorithms, methods, functions, processes, flows, and procedures as described in the present disclosure.

The computer 802 also includes a database 806 that can hold data for the computer 802 and other components connected to the network 830 (whether illustrated or not). For example, database 806 can be an in-memory, conventional, or a database storing data consistent with the present disclosure. In some implementations, database 806 can be a combination of two or more different database types (for example, hybrid in-memory and conventional databases) according to particular needs, desires, or particular implementations of the computer 802 and the described functionality. Although illustrated as a single database 806 in FIG. 8, two or more databases (of the same, different, or combination of types) can be used according to particular needs, desires, or particular implementations of the computer 802 and the described functionality. While database 806 is illustrated as an internal component of the computer 802, in alternative implementations, database 806 can be external to the computer 802.

The computer 802 also includes a memory 807 that can hold data for the computer 802 or a combination of components connected to the network 830 (whether illustrated or not). Memory 807 can store any data consistent with the present disclosure. In some implementations, memory 807 can be a combination of two or more different types of memory (for example, a combination of semiconductor and magnetic storage) according to particular needs, desires, or particular implementations of the computer 802 and the described functionality. Although illustrated as a single memory 807 in FIG. 8, two or more memories 807 (of the same, different, or combination of types) can be used according to particular needs, desires, or particular implementations of the computer 802 and the described functionality. While memory 807 is illustrated as an internal component of the computer 802, in alternative implementations, memory 807 can be external to the computer 802.

The application 808 can be an algorithmic software engine providing functionality according to particular needs, desires, or particular implementations of the computer 802 and the described functionality. For example, application 808 can serve as one or more components, modules, or applications. Further, although illustrated as a single application 808, the application 808 can be implemented as multiple applications 808 on the computer 802. In addition, although illustrated as internal to the computer 802, in alternative implementations, the application 808 can be external to the computer 802.

The computer 802 can also include a power supply 814. The power supply 814 can include a rechargeable or non-rechargeable battery that can be configured to be either user- or non-user-replaceable. In some implementations, the power supply 814 can include power-conversion and management circuits, including recharging, standby, and power management functionalities. In some implementations, the power supply 814 can include a power plug to allow the computer 802 to be plugged into a wall socket or a power source to, for example, power the computer 802 or recharge a rechargeable battery.

There can be any number of computers 802 associated with, or external to, a computer system containing computer 802, with each computer 802 communicating over network 830. Further, the terms “client,” “user,” and other appropriate terminology can be used interchangeably, as appropriate, without departing from the scope of the present disclosure. Moreover, the present disclosure contemplates that many users can use one computer 802 and one user can use multiple computers 802.

Described implementations of the subject matter can include one or more features, alone or in combination.

For example, in a first implementation, a computer-implemented method includes the following. Readings of actual field sensors corresponding to virtual sensors modeled in a virtual model are monitored. A deviation between an actual sensor reading (ASR) and a virtual sensor reading (VSR) is determined. When only the VSR is deviating and when sensor readings of sensors that are proximate to the actual sensor correspond to the VSR, then a determination is made that the ASR is invalid and that the actual sensor requires revalidation and recalibration. When only the ASR is deviating and when sensor readings of sensors that are proximate to the actual sensor correspond to the ASR, then a determination is made that the VSR is invalid and that the virtual sensor requires revalidation and recalibration. When both of the VSR and the ASR are deviating from their respective design ranges and when sensor readings of sensors that are proximate to the actual sensor do not correspond to either the ASR or the VSR, then a determination is made that both the ASR and the VSR are invalid and that both the actual sensor and the virtual sensor require revalidation and recalibration.

The foregoing and other described implementations can each, optionally, include one or more of the following features:

A first feature, combinable with any of the following features, where the actual field sensors include temperature sensors, pressure sensors, and flow sensors.

A second feature, combinable with any of the previous or following features, where determining the deviation between the ASR and the VSR includes performing calculations using instantaneous sensor readings.

A third feature, combinable with any of the previous or following features, where determining the deviation between the ASR and the VSR is based on average deviations of historical readings from both types of sensors over a designated time period.

A fourth feature, combinable with any of the previous or following features, where determining that the sensor readings of the sensors that are proximate to the actual sensor correspond to the sensor includes using a set of validation rules.

A fifth feature, combinable with any of the previous or following features, where the set of validation rules includes mathematical functions based on inequalities between the sensors.

A sixth feature, combinable with any of the previous or following features, where determining that the sensor readings of the sensors that are proximate to the actual sensor correspond to the sensor includes using a table correlating the sensors, where the table is generated from an offline simulation model based on process design conditions of multiple sensors.

A seventh feature, combinable with any of the previous or following features, determining that the sensor readings of the sensors that are proximate to the actual sensor correspond to the sensor includes using a machine learning model correlating each sensor with its related sensors.

An eighth feature, combinable with any of the previous or following features, where determining that only the VSR is deviating includes determining that the deviation D in

$$D = \frac{V S R - A S R}{V S R} * 100$$

is greater than a threshold positive deviation and that changes in ASR previous values over a specified period of time are below an ASR change threshold.

A ninth feature, combinable with any of the previous or following features, the method further including: determining that only the ASR is deviating includes determining that the deviation D in

$$D = \frac{V S R - A S R}{V S R} * 100$$

is less than a threshold negative deviation and that changes in VSR previous values over a specified period of time are below a VSR change threshold.

In a second implementation, a non-transitory, computer-readable medium stores one or more instructions executable by a computer system to perform operations including the following. Readings of actual field sensors corresponding to virtual sensors modeled in a virtual model are monitored. A deviation between an actual sensor reading (ASR) and a virtual sensor reading (VSR) is determined. When only the VSR is deviating and when sensor readings of sensors that are proximate to the actual sensor correspond to the VSR, then a determination is made that the ASR is invalid and that the actual sensor requires revalidation and recalibration. When only the ASR is deviating and when sensor readings of sensors that are proximate to the actual sensor correspond to the ASR, then a determination is made that the VSR is invalid and that the virtual sensor requires revalidation and recalibration. When both of the VSR and the ASR are deviating from their respective design ranges and when sensor readings of sensors that are proximate to the actual sensor do not correspond to either the ASR or the VSR, then a determination is made that both the ASR and the VSR are invalid and that both the actual sensor and the virtual sensor require revalidation and recalibration.

The foregoing and other described implementations can each, optionally, include one or more of the following features:

A first feature, combinable with any of the previous or following features, where determining that the sensor readings of the sensors that are proximate to the actual sensor correspond to the sensor includes using a table correlating the sensors, where the table is generated from an offline simulation model based on process design conditions of multiple sensors.

A second feature, combinable with any of the previous or following features, determining that the sensor readings of the sensors that are proximate to the actual sensor correspond to the sensor includes using a machine learning model correlating each sensor with its related sensors.

A third feature, combinable with any of the previous or following features, where determining that only the VSR is deviating includes determining that the

$$D = \frac{V S R - A S R}{V S R} * 100$$

is greater than a threshold positive deviation and that changes in ASR previous values over a specified period of time are below an ASR change threshold.

A fourth feature, combinable with any of the previous or following features, the method further including: determining that only the ASR is deviating includes determining that the deviation D in

$$D = \frac{V S R - A S R}{V S R} * 100$$

is less than a threshold negative deviation and that changes in VSR previous values over a specified period of time are below a VSR change threshold.

In a third implementation, a computer-implemented system includes one or more processors and a non-transitory computer-readable storage medium coupled to the one or more processors and storing programming instructions for execution by the one or more processors. The programming instructions instruct the one or more processors to perform operations including the following. Readings of actual field sensors corresponding to virtual sensors modeled in a virtual model are monitored. A deviation between an actual sensor reading (ASR) and a virtual sensor reading (VSR) is determined. When only the VSR is deviating and when sensor readings of sensors that are proximate to the actual sensor correspond to the VSR, then a determination is made that the ASR is invalid and that the actual sensor requires revalidation and recalibration. When only the ASR is deviating and when sensor readings of sensors that are proximate to the actual sensor correspond to the ASR, then a determination is made that the VSR is invalid and that the virtual sensor requires revalidation and recalibration. When both of the VSR and the ASR are deviating from their respective design ranges and when sensor readings of sensors that are proximate to the actual sensor do not correspond to either the ASR or the VSR, then a determination is made that both the ASR and the VSR are invalid and that both the actual sensor and the virtual sensor require revalidation and recalibration.

The foregoing and other described implementations can each, optionally, include one or more of the following features:

A first feature, combinable with any of the previous or following features, where determining that the sensor readings of the sensors that are proximate to the actual sensor correspond to the sensor includes using a table correlating the sensors, where the table is generated from an offline simulation model based on process design conditions of multiple sensors.

A second feature, combinable with any of the previous or following features, determining that the sensor readings of the sensors that are proximate to the actual sensor correspond to the sensor includes using a machine learning model correlating each sensor with its related sensors.

A third feature, combinable with any of the previous or following features, where determining that only the VSR is deviating includes determining that the deviation D in

$$D = \frac{V S R - A S R}{V S R} * 100$$

is greater than a threshold positive deviation and that changes in ASR previous values over a specified period of time are below an ASR change threshold.

A fourth feature, combinable with any of the previous or following features, the method further including: determining that only the ASR is deviating includes determining that the deviation D in

$$D = \frac{V S R - A S R}{V S R} * 100$$

is less than a threshold negative deviation and that changes in VSR previous values over a specified period of time are below a VSR change threshold.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at the application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method, comprising:
monitoring readings of actual field sensors corresponding to virtual sensors modeled in a virtual model;
determining a deviation between an actual sensor reading (ASR) and a virtual sensor reading (VSR);
when only the VSR is deviating and when sensor readings of sensors that are proximate to the actual sensor correspond to the VSR, then:
determining that the ASR is invalid and that the actual sensor requires revalidation and recalibration;
when only the ASR is deviating and when sensor readings of sensors that are proximate to the actual sensor correspond to the ASR, then:
determining that the VSR is invalid and that the virtual sensor requires revalidation and recalibration; and
when both of the VSR and the ASR are deviating from their respective design ranges and when sensor readings of sensors that are proximate to the actual sensor do not correspond to either the ASR or the VSR, then:
determining that both the ASR and the VSR are invalid and that both the actual sensor and the virtual sensor require revalidation and recalibration.

2. The computer-implemented method of claim 1, wherein the actual field sensors include temperature sensors, pressure sensors, and flow sensors.

3. The computer-implemented method of claim 1, wherein determining the deviation between the ASR and the VSR includes performing calculations using instantaneous sensor readings.

4. The computer-implemented method of claim 1, wherein determining the deviation between the ASR and the VSR is based on average deviations of historical readings from both types of sensors over a designated time period.

5. The computer-implemented method of claim 1, wherein determining that the sensor readings of the sensors that are proximate to the actual sensor correspond to the sensor includes using a set of validation rules.

6. The computer-implemented method of claim 5, wherein the set of validation rules includes mathematical functions based on inequalities between the sensors.

7. The computer-implemented method of claim 1, wherein determining that the sensor readings of the sensors that are proximate to the actual sensor correspond to the sensor includes using a table correlating the sensors, wherein the table is generated from an offline simulation model based on process design conditions of multiple sensors.

8. The computer-implemented method of claim 1, wherein determining that the sensor readings of the sensors that are proximate to the actual sensor correspond to the sensor includes using a machine learning model correlating each sensor with its related sensors.

9. The computer-implemented method of claim 1, wherein determining that only the VSR is deviating includes determining that the deviation D in
$$D = \frac{V S R - A S R}{V S R} * 100$$
is greater than a threshold positive deviation and that changes in ASR previous values over a specified period of time are below an ASR change threshold.

10. The computer-implemented method of claim 1, wherein determining that only the ASR is deviating includes determining that the deviation D in
$$D = \frac{V S R - A S R}{V S R} * 100$$
is less than a threshold negative deviation and that changes in VSR previous values over a specified period of time are below a VSR change threshold.

11. A non-transitory, computer-readable medium storing one or more instructions executable by a computer system to perform operations comprising:
monitoring readings of actual field sensors corresponding to virtual sensors modeled in a virtual model;
determining a deviation between an actual sensor reading (ASR) and a virtual sensor reading (VSR);
when only the VSR is deviating and when sensor readings of sensors that are proximate to the actual sensor correspond to the VSR, then:
determining that the ASR is invalid and that the actual sensor requires revalidation and recalibration;
when only the ASR is deviating and when sensor readings of sensors that are proximate to the actual sensor correspond to the ASR, then:
determining that the VSR is invalid and that the virtual sensor requires revalidation and recalibration; and
when both of the VSR and the ASR are deviating from their respective design ranges and when sensor readings of sensors that are proximate to the actual sensor do not correspond to either the ASR or the VSR, then:
determining that both the ASR and the VSR are invalid and that both the actual sensor and the virtual sensor require revalidation and recalibration.

12. The non-transitory, computer-readable medium of claim 11, wherein determining that the sensor readings of the sensors that are proximate to the actual sensor correspond to the sensor includes using a table correlating the sensors, wherein the table is generated from an offline simulation model based on process design conditions of multiple sensors.

13. The non-transitory, computer-readable medium of claim 11, wherein determining that the sensor readings of the sensors that are proximate to the actual sensor correspond to the sensor includes using a machine learning model correlating each sensor with its related sensors.

14. The non-transitory, computer-readable medium of claim 11, wherein determining that only the VSR is deviating includes determining that the deviation D in
$$D = \frac{V S R - A S R}{V S R} * 100$$
is greater than a threshold positive deviation and that changes in ASR previous values over a specified period of time are below an ASR change threshold.

15. The non-transitory, computer-readable medium of claim 11, wherein determining that only the ASR is deviating includes determining that the deviation D in
$$D = \frac{V S R - A S R}{V S R} * 100$$
is less than a threshold negative deviation and that changes in VSR previous values over a specified period of time are below a VSR change threshold.

16. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
monitoring readings of actual field sensors corresponding to virtual sensors modeled in a virtual model;
determining a deviation between an actual sensor reading (ASR) and a virtual sensor reading (VSR);
when only the VSR is deviating and when sensor readings of sensors that are proximate to the actual sensor correspond to the VSR, then:
determining that the ASR is invalid and that the actual sensor requires revalidation and recalibration;
when only the ASR is deviating and when sensor readings of sensors that are proximate to the actual sensor correspond to the ASR, then:
determining that the VSR is invalid and that the virtual sensor requires revalidation and recalibration; and
when both of the VSR and the ASR are deviating from their respective design ranges and when sensor readings of sensors that are proximate to the actual sensor do not correspond to either the ASR or the VSR, then:
determining that both the ASR and the VSR are invalid and that both the actual sensor and the virtual sensor require revalidation and recalibration.

17. The computer-implemented system of claim 16, wherein determining that the sensor readings of the sensors that are proximate to the actual sensor correspond to the sensor includes using a table correlating the sensors, wherein the table is generated from an offline simulation model based on process design conditions of multiple sensors.

18. The computer-implemented system of claim 16, wherein determining that the sensor readings of the sensors that are proximate to the actual sensor correspond to the sensor includes using a machine learning model correlating each sensor with its related sensors.

19. The computer-implemented system of claim 16, wherein determining that only the VSR is deviating includes determining that the deviation D in
$$D = \frac{V S R - A S R}{V S R} * 100$$
is greater than a threshold positive deviation and that changes in ASR previous values over a specified period of time are below an ASR change threshold.

20. The computer-implemented system of claim 16, wherein determining that only the ASR is deviating includes determining that the deviation D in
$$D = \frac{V S R - A S R}{V S R} * 100$$
is less than a threshold negative deviation and that changes in VSR previous values over a specified period of time are below a VSR change threshold.
